(19) United States
(12) Patent Application Publication
(10) Pub. No.: US 2017/0330982 A1
(43) Pub. Date: Nov. 16, 2017

(54) PHOTO DETECTOR, PHOTO DETECTION DEVICE, AND LIDAR DEVICE

(71) Applicant: Kabushiki Kaisha Toshiba, Tokyo (JP)

(72) Inventors: Toshiya Yonehara, Kawasaki (JP); Kazuhiro Suzuki, Tokyo (JP); Rei Hasegawa, Yokohama (JP)

(73) Assignee: Kabushiki Kaisha Toshiba

(21) Appl. No.: 15/451,531

(22) Filed: Mar. 7, 2017

(30) Foreign Application Priority Data
May 11, 2016 (JP) 2016-095358

(51) Int. Cl. H01L 31/0232; H01L 31/0236; G01S 7/481; H01L 27/144; H01L 31/107; H01L 31/028

(52) U.S. Cl. CPC H01L 31/02327; H01L 31/107; H01L 31/028; G01S 7/4816; H01L 27/1446; H01L 31/02363

(57) ABSTRACT

In one embodiment, a photo detector is provided with a semiconductor layer having a light receiving surface, a first reflective material which is provided on a side opposite to the light receiving surface side of the semiconductor layer and reflects a light incident from the light receiving surface, and a slope portion provided on a side surface of the semiconductor layer.

### CROSS-REFERENCE TO RELATED APPLICATION

This application is based upon and claims the benefit of priority from the prior Japanese Patent Application No. 2016-095358, filed on May 11, 2016, the entire contents of which are incorporated herein by reference.

### FIELD

Embodiments described herein relate generally to a photo detector, a photo detection device, and a LIDAR (Laser Imaging Detection and Ranging) device.

### BACKGROUND

A photo detector using an avalanche photo diode (APD) detects weak light, and amplifies a signal to be outputted. When an APD is made of silicon (Si), light sensitivity characteristic of the photo detector largely depends on absorption characteristic of silicon. The APD made of silicon most absorbs light with a wavelength of 400-600 nm. The APD hardly has sensitivity to light of a near infra-red wavelength band. In order to improve the sensitivity of a photo detector using silicon, a device is known in which a depletion layer is made very thick, such as several ten μm, to have sensitivity to light of a near infra-red wavelength band. However, a drive voltage of the photo detector might become very high, such as several hundred volts.

Accordingly, in a photo detector using silicon, a structure to confine light inside the photo detector has been considered, in order to enhance detection efficiency of light of a near infra-red wavelength band.

### BRIEF DESCRIPTION OF THE DRAWINGS

FIG. 1A is a diagram showing a photo detector of a first embodiment.

FIG. 1B is a diagram showing the photo detector of the first embodiment.

FIG. 1C is a diagram showing characteristics of the photo detector of the first embodiment.

FIG. 2A is a diagram showing a photo detector of the first embodiment.

FIG. 2B is a diagram showing the photo detector of the first embodiment.

FIG. 3 is a diagram showing the relation between a slope angle and an area ratio in the photo detector of the first embodiment.

FIG. 4A is a diagram showing a photo detection device of a second embodiment.

FIG. 4B is a diagram showing a photo detection device of the second embodiment.

FIG. 4C is a diagram showing characteristics of the photo detection device of the second embodiment.

FIG. 5 is a diagram showing a photo detector of a third embodiment.

FIG. 6A is a diagram showing a photo detector of a fourth embodiment.

FIG. 6B is a diagram showing a photo detector of the fourth embodiment.

FIG. 6C is a diagram showing a photo detector of the fourth embodiment.

FIG. 7A is a diagram showing a photo detector of a fifth embodiment.

FIG. 7B is a diagram showing a photo detector of the fifth embodiment.

FIG. 7C is a diagram showing characteristics of the photo detector of the fifth embodiment.

FIG. 8A is a diagram showing a photo detection device of a sixth embodiment.

FIG. 8B is a diagram showing the photo detection device of the sixth embodiment.

FIG. 8C is a diagram showing the photo detection device of the sixth embodiment.

FIG. 9A is a diagram showing the photo detection device of the sixth embodiment.

FIG. 9B is a diagram showing the photo detection device of the sixth embodiment.

FIG. 9C is a diagram showing the photo detection device of the sixth embodiment.

FIG. 9D is a diagram showing the photo detection device of the sixth embodiment.

FIG. 10A is a diagram showing a photo detection device of a seventh embodiment.

FIG. 10B is a circuit diagram of the photo detection device of the seventh embodiment.

FIG. 10C is a diagram showing the photo detection device of the seventh embodiment.

FIG. 11A is a diagram showing a photo detector of an eighth embodiment.

FIG. 11B is a diagram showing a photo detector of the eighth embodiment.

FIG. 11C is a diagram showing a photo detector of the eighth embodiment.

FIG. 12A is a diagram showing a manufacturing method of a photo detector.

FIG. 12B is a diagram showing the manufacturing method of a photo detector.

FIG. 12C is a diagram showing the manufacturing method of a photo detector.

FIG. 12D is a diagram showing the manufacturing method of a photo detector.

FIG. 12E is a diagram showing the manufacturing method of a photo detector.

FIG. 13A is a diagram showing the manufacturing method of a photo detector.

FIG. 13B is a diagram showing the manufacturing method of a photo detector.

FIG. 14A is a diagram showing a configuration of a measuring system.

FIG. 14B is a diagram showing a configuration of a measuring system.

FIG. 14C is a diagram showing a configuration of a measuring system.

FIG. 15 is a diagram showing a LIDAR device.

### DETAILED DESCRIPTION

According to one embodiment, a photo detector is provided with a semiconductor layer having a light receiving surface, a first reflective material which is provided on a side opposite to the light receiving surface side of the semiconductor layer and reflects a light incident from the light receiving surface, and a slope portion provided on a side surface of the semiconductor layer.

Hereinafter, further embodiments will be described with reference to the drawings. Ones with the same symbols show the similar ones. In addition, the drawings are schematic or conceptual, and accordingly, the relation between a thickness and a width in each portion, and a ratio coefficient of sizes between portions are not necessarily identical to those of the actual ones. In addition, even when the same portions are shown, the dimensions and the ratio coefficients thereof may be shown differently depending on the drawings.

### First Embodiment

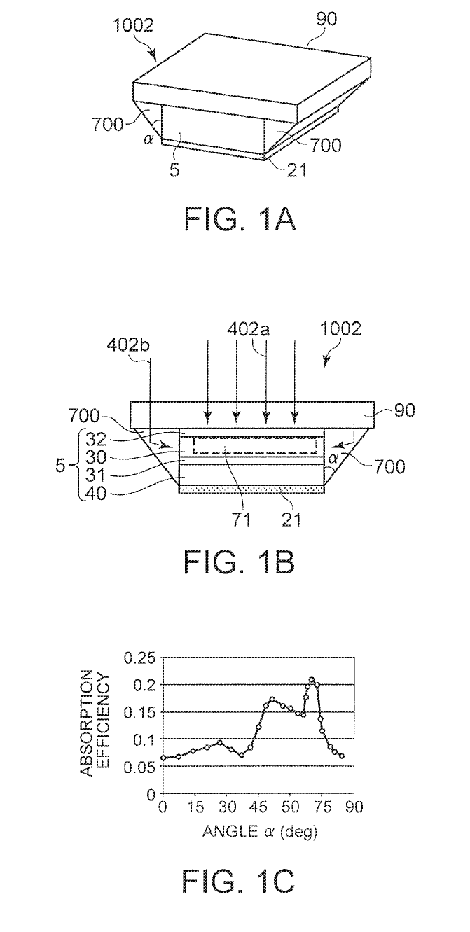

FIG. 1A is a diagram showing a photo detector 1002, FIG. 1B is a sectional view of the photo detector 1002, and FIG. 1C is a diagram showing a light absorption efficiency of the photo detector 1002.

In FIG. 1A, the photo detector 1002 is composed of a substrate 90, a semiconductor layer 5, an optical path conversion portion 700, and a reflective material 21.

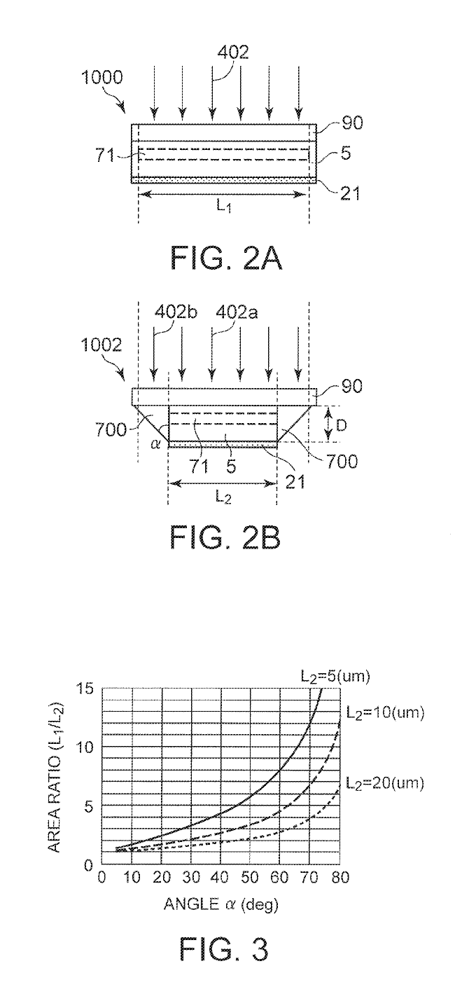

In FIG. 1B, the semiconductor layer 5 is composed of a p⁺ type semiconductor layer 32, a p⁻ type semiconductor layer 30, a p⁺ type semiconductor layer 31, and an n type semiconductor layer 40. In FIG. 2A or later described below, the description of the p⁺ type semiconductor layer 32, the p⁻ type semiconductor layer 30, the type semiconductor layer 31, and the n type semiconductor layer 40 which compose the semiconductor layer 5 will be omitted, and they will be simply shown as the semiconductor layer 5.

The p⁺ type semiconductor layer 32 of the semiconductor layer 5 is a light receiving surface.

A first electrode not shown is provided on the light receiving surface side of the semiconductor layer 5.

The substrate 90 is provided on the p⁺ type semiconductor layer 32 side serving as the light receiving surface of the semiconductor layer 5. The substrate 90 transmits light. The substrate 90 supports the semiconductor layer 5. It is possible that the substrate 90 is not provided.

The reflective material (first reflective material) 21 is provided on a side opposite to the p⁺ type semiconductor layer 32 side serving as the light receiving surface of the semiconductor layer 5. The reflective material 21 may be provided with a function of an electrode as well.

The semiconductor layer 5 is composed of a p type semiconductor layer and an n type semiconductor layer in this order in the direction from the light receiving surface toward the reflective material 21.

The semiconductor layer 5 is composed of the p⁺ type semiconductor layer 32, the p⁻ type semiconductor layer 30, the p⁺ type semiconductor layer 31, and the n type semiconductor layer 40 in this order, in the direction from the light receiving surface toward the reflective material 21. The semiconductor layer 5 may not be provided with the p⁺ type semiconductor layers 31, 32, and may be a laminated structure of a p type semiconductor layer and an n type semiconductor layer. The semiconductor layer 5 may be composed of an n type semiconductor layer and a p type semiconductor layer in this order in the direction from the light receiving surface toward the reflective material.

The semiconductor layer 5 may be composed of an n⁺ type semiconductor layer, an n⁻ type semiconductor layer, an n⁺ type semiconductor layer, and a p type semiconductor layer in this order, in the direction from the light receiving surface toward the reflective material 21.

The semiconductor layer 5 is composed of Si (silicon). It is more preferable to select Si as the material of the semiconductor layer 5, because the manufacturing cost thereof is not expensive.

It is supposed that the light incident into the p⁻ type semiconductor layer 32 serving as the light receiving surface is near infrared light with a wavelength of not less than 750 nm and not more than 1000 nm.

A length of the semiconductor layer 5 in the direction from the light receiving surface toward the reflective material 21 is not less than 1 μm and not more than 15 μm.

The optical path conversion portion (slope portion) 700 is provided on a side surface of the semiconductor layer 5. The optical path conversion portion 700 may be formed on a part of the semiconductor 5, that is, integrally with the semiconductor layer 5, or may be formed separately from the semiconductor layer 5. The optical path conversion portion 700 of the semiconductor layer 5 has a slope surface. An angle of the slope surface, to the direction from the reflective material 21 of the semiconductor layer 5 toward the p⁺ type semiconductor layer 32 of the light receiving surface is α (deg).

The substrate 90 may be adhered to the semiconductor layer 5 via an adhesive layer 80 not shown, for example.

A depletion layer 71 is formed inside the semiconductor layer 5. A light 402a incident from the light receiving surface is absorbed by the depletion layer 71. In the depletion layer 71, the light 402a is converted into electron-hole pairs. The light 402a which has been incident from the light receiving surface and has passed through the depletion layer 71 reaches the reflective material 21. The light 402a is reflected by the reflective material 21 in the direction of the depletion layer 71.

A light 402b incident from the light receiving surface into the optical path conversion portion 700 is reflected by the slope surface of the optical path conversion portion 700, and is incident into the depletion layer 71.

When a voltage serving as a reverse bias to the pn junction of the p⁻ type semiconductor layer 30 and the n type semiconductor layer 40 is applied, between the first electrode not shown provided on the light receiving surface side of the semiconductor layer 5 and the reflective material 21, electrons of the electron-hole pairs flow in the direction of the n type semiconductor layer 40. Holes of the electron-hole pairs flow in the direction of the p⁺ type semiconductor layer 32. At this time, when the voltage applied to the pn junction is increased, the flowing speeds of the electrons and the holes are accelerated within the depletion layer 71. Particularly, in the p⁺ type semiconductor layer 31, electrons come in collision with atoms in the p⁻ type semiconductor layer 30, to generate new electron-hole pairs. This phenomenon is called avalanche amplification. The avalanche amplification is a reaction which occurs in chains. The avalanche amplification is generated, and thereby the photo detector 1002 can detect weak light.

A distance between the first electrodes and the reflective material 21 is not less than 1 μm and not more than 15 μm, for example. If this distance is smaller than 1 μm, a region of the depletion layer 71 becomes small. Accordingly, a detection efficiency and an amplification factor of light of the photo detector 1002 become low. If this distance is larger than 15 μm, light absorption at outside the depletion layer 71 might increases, to cause reduction of the detection efficiency of light.

In the photo detector 1002, after the avalanche amplification has occurred, a dead time when light cannot be detected is generated. The dead time of the photo detector 1002 is made short, and thereby the photo detector 1002 can detect light efficiently. In order to make the dead time of the photo detector 1002 short, it is necessary to promptly take out the electrons and holes existing within the photo detector 1002 to the outside. At this time, a speed at which the electrons and holes are taken out to the outside of the photo detector 1002 is determined by a capacitance C of the photo detector 1002. The capacitance C depends on an area S of the p⁺ type semiconductor layer 32 serving as the light receiving surface. The smaller the area S of the p⁺ type semiconductor layer 32 serving as the light receiving surface is, the smaller the capacitance C of the photo detector 1002 becomes. The smaller the area S of the p⁺ type semiconductor layer 32 serving as the light receiving surface is, the more promptly the electrons and holes existing inside the photo detector 1002 can be taken out to the outside.

For the reason, it is preferable that the area S of the p⁺ type semiconductor layer 32 serving as the light receiving surface is not more than 100 μm×100 μm. On the other hand, when the area S of the p⁺ type semiconductor layer 32 serving as the light receiving surface is too small, the detection sensitivity of the photo detector 1002 is decreased. In order to make the reduction of the dead time compatible with the detection sensitivity of light, it is preferable that regarding the longitudinal direction and the lateral direction, a length in the longitudinal direction is not less than 5 μm and not more than 50 μm, and a length in the lateral direction is not less than 5 μm and not more than 50 μm. If the length is smaller than 5 μm, the distance of the depletion layer in the lateral direction becomes shorter, and thereby the light might not be absorbed but might pass through. In addition, if the length is larger than 50 μm, taking the image resolution into consideration when the photo detectors are to be arrayed, the required image resolution might not be obtained.

FIG. 1C shows the relation between a light absorption efficiency of the photo detector 1002, and the angle α between the side surface of the semiconductor layer 5 and the slope surface of the optical path conversion portion 700.

The vertical axis shows a light absorption efficiency of the photo detector 1002, and the horizontal axis shows the angle α of the slope surface of the optical path conversion portion 700. FIG. 1C is calculated by simulation. The condition of the simulation was that the substrate 90 is made of glass with a thickness of 300 μm, the semiconductor layer 5 is made of silicon (Si) with a thickness of 8 μm, and the reflective material 21 is made of aluminum (Al) with a thickness of 150 nm. The optical path conversion portion 700 that is a part of the semiconductor layer 5 is also silicon (Si). That the angle α of the slope surface is 0 degree means a case in which the photo detector 1002 is not provided with the optical path conversion portion 700. A wavelength of the light is decided as 910 nm.

In FIG. 1C, a case is shown in which a light intensity of the light 402a which has been incident into a region corresponding to an area region of the depletion layer 71 is decided as 1.

When the angle α of the slope surface of the optical path conversion portion 700 is not less than 10 degrees and not more than 80 degrees, a light absorption efficiency of the photo detector 1002 is improved. For the reason, it is preferable that the angle α of the slope surface of the optical path conversion portion 700 is not less than 10 degrees and not more than 80 degrees. In addition, when the angle α of the slope surface of the optical path conversion portion 700 is not less than 45 degrees and not more than 75 degrees, a light absorption efficiency of the photo detector 1002 is further improved. For the reason, it is more preferable that the angle α of the slope surface of the optical path conversion portion 700 is not less than 45 degrees and not more than 75 degrees.

If the angle α is smaller than 10 degrees, an effect of providing the optical path conversion portion 700 is small. In addition, if the angle α is larger than 80 degrees, a ratio in which the optical path conversion portion 700 occupies in the photo detector 1002 becomes large, and as a result, an area of the photo detector 1002 might become large. If the area of the photo detector 1002 becomes too large, in the case of obtaining two-dimensional information by arranging a plurality of the photo detectors 1002, the resolution per the photo detector 1002 might deteriorate.

The optical path conversion portion 700 is provided, and thereby a detection area of light of the photo detector 1002 is practically increased. Accordingly, it is possible to effectively collect light in the photo detector 1002.

FIG. 2A is a diagram showing a photo detector 1000, and FIG. 2B is a diagram showing the photo detector 1002.

In FIG. 2A, the semiconductor layer 5 of the photo detector 1000 is shown by simplification.

In FIG. 2A, and FIG. 2B, the photo detector 1000 and the photo detector 1002 are shown so that the regions of light which the photo detector 1000 and the photo detector 1002 respectively detect become the same.

In FIG. 2A, the photo detector 1000 is not provided with the optical path conversion portion 700. The photo detector 1000 detects a light 402. When the photo detector 1000 is used in a LIDAR device, a large part of the light 402 is approximately vertically incident into the photo detector 1000.

When silicon is used as the material of the semiconductor layer 5, a refractive index of the semiconductor layer 5 in light with a wavelength of 700-1000 nm is about 3.7. For the reason, when the light 402 is incident from air with a refractive index of 1.0 into the semiconductor layer 5 with a refractive index of 3.7, the light 402 which has been incident into the semiconductor layer 5 is approximately vertical to the semiconductor layer 5. For example, no matter at what angle the light 402 is incident on the incident surface of the photo detector 1000, the light 402 is incident into the semiconductor layer 5 at an angle of less than about 15.7 (deg).

A length of the depletion layer 71 of the photo detector 1000 in the horizontal direction is decided as L₁. A length of the depletion layer 71 of the photo detector 1002 in the horizontal direction is decided as L₂, and a length of the semiconductor layer 5 in the direction from the light receiving surface of the photo detector 1002 toward the reflective material 21 is decided as D.

In FIG. 2B, the photo detector 1002 makes the optical path conversion portion 700 reflect the light 402b, and thereby can make the light 402b incident into the depletion layer 71. For the reason, it is possible to make the region of the depletion layer 71 smaller in the photo detector 1002 than in the photo detector 1000.

When the photo detectors 1000, 1002 are used as an avalanche photo detector, for example, sizes of the capacitances of the photo detectors 1000, 1002 affect the response speeds of the photo detectors 1000, 1002, respectively. The smaller an area of the depletion layer 71 serving as the photo detection region is, the smaller a capacitance of each of the photo detectors 1000, 1002 becomes. The smaller the capacitances of the photo detectors 1000, 1002 are, at the higher speed the photo detectors 1000, 1002 can respond, respectively. Since the region of the depletion layer 71 in the photo detector 1002 is smaller than in the photo detector 1000, the photo detector 1002 can respond at a higher speed.

FIG. 3 is a diagram showing the relation between the angle α of the slope surface of the optical path conversion portion 700 and an area ratio (L₁/L₂) in the photo detector 1002.

The vertical axis shows an area ratio, and the horizontal axis shows the angle α of the slope surface of the optical path conversion portion 700. The length D of the semiconductor layer 5 of the photo detector 1002 is decided as 10 μm. The lengths L₂ of the depletion layers 71 of the photo detector 1002 in the horizontal direction are decided as 5 μm, 10 μm, and 20 μm.

In FIG. 3, the smaller a value of L₂ is, the larger a value of L₁/L₂ becomes. That is, the smaller a value of the length L₂ of the depletion layer 71 of the photo detector 1002 in the horizontal direction is, the larger the effect of providing the optical path conversion portion 700 becomes. In addition, when L₁ is made constant, the optical path conversion portion 700 is provided, and thereby a value of L₂ can be made small, and as a result the capacitance of the photo detector 1002 becomes small, and accordingly, the photo detector 1002 can respond at a high speed.

### Second Embodiment

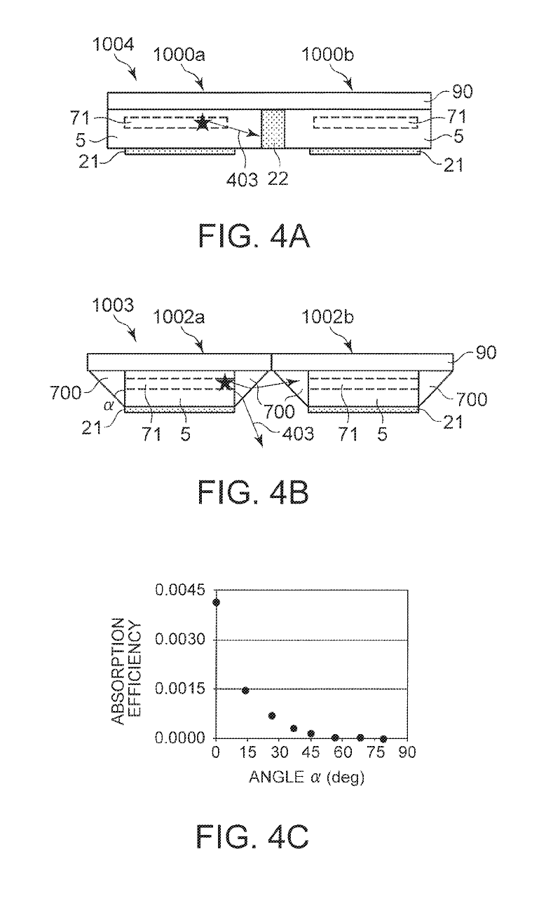

FIG. 4A is a diagram showing a photo detection device 1004, FIG. 4B is a diagram showing a photo detection device 1003, and FIG. 4C is a diagram showing the relation between the angle α and a light absorption efficiency in the photo detection device 1003.

The same symbols are given to the same portions as in FIGS. 1A-1C, FIGS. 2A, 2B, and the description thereof will be omitted.

In FIG. 4A, the photo detection device 1004 is obtained by aligning the two photo detectors 1000. They are decided as a photo detector 1000a and a photo detector 1000b, respectively. The two photo detectors 1000a and 1000b share the substrate 90.

When the photo detection device 1004 is used as an avalanche photo detection device, the photo detector 1000a might generate a light 403 by excess energy, in the avalanche amplification process. At this time, the generated light 403 is incident into the adjacent photo detector 1000b, and might be detected by the photo detector 1000b. Accordingly, the photo detection device might respond not to the light 402 which is to be normally detected, but to the irrelevant light 403. As a method to solve this, a partition made of a metal portion 22 is provided between the depletion layers 71 composing the photo detection device 1004. By this means, the light 403 is not incident into the photo detector 1000b.

In FIG. 4B, the photo detection device 1003 is obtained by aligning the two photo detectors 1002. They are decided as a photo detector 1002a and a photo detector 1002b, respectively.

In the case of the photo detection device 1003 of FIG. 4B, the light 403 generated in the photo detector 1002a is refracted by the slope surface of the optical path conversion portion 700, and goes outside the photo detector 1002a. For the reason, a possibility that the light 403 is incident into the photo detector 1002b adjacent to the photo detector 1002a is suppressed. The photo detection device 1003 may not be provided with the metal portion 22.

In FIG. 4C, a light absorption efficiency is shown in which the light 403 (wavelength: 905 nm) generated in the depletion layer 71 of the photo detector 1002a of the photo detection device 1003 is detected by the adjacent photo detector 1002b.

The vertical axis shows an absorption efficiency of the light 403 in the photo detector 1002b, and the horizontal axis shows the angle α of the slope surface of the optical path conversion portion 700 in the photo detector 1002b. FIG. 4C is calculated by simulation. The condition of the simulation was that the substrate 90 is made of glass, the semiconductor layer 5 is made of silicon with a thickness of 8 μm, the reflective material 21 is made of aluminum with a thickness of 150 nm. The optical path conversion portion 700 is made of silicon.

In FIG. 4C, it was found that the optical path conversion portion 700 of the photo detection device 1003 is provided, and when the angle α of the slope surface of the optical path conversion portion 700 is increased, the absorption efficiency of the light 403 detected in the photo detector 1002b is decreased. For example, in the case that the angle α of the slope surface of the optical path conversion portion 700 is not less than 60 degrees and not more than 80 degrees, the absorption efficiency due to misdetection of the light 403 is nearly zero.

As shown in FIG. 4C, the optical path conversion portion 700 is provided, and thereby the photo detection device 1003 can suppress misdetection of the light 403. Accordingly, the photo detection device 1003 can not only detect the light 403 effectively, but also suppress the misdetection due to the light 403. In the present embodiment, the photo detection device 1003 obtained by aligning a plurality of the photo detectors 1002 has been shown, but without limited to the photo detector 1002, a plurality of photo detectors described later may be aligned to form a photo detection device.

### Third Embodiment

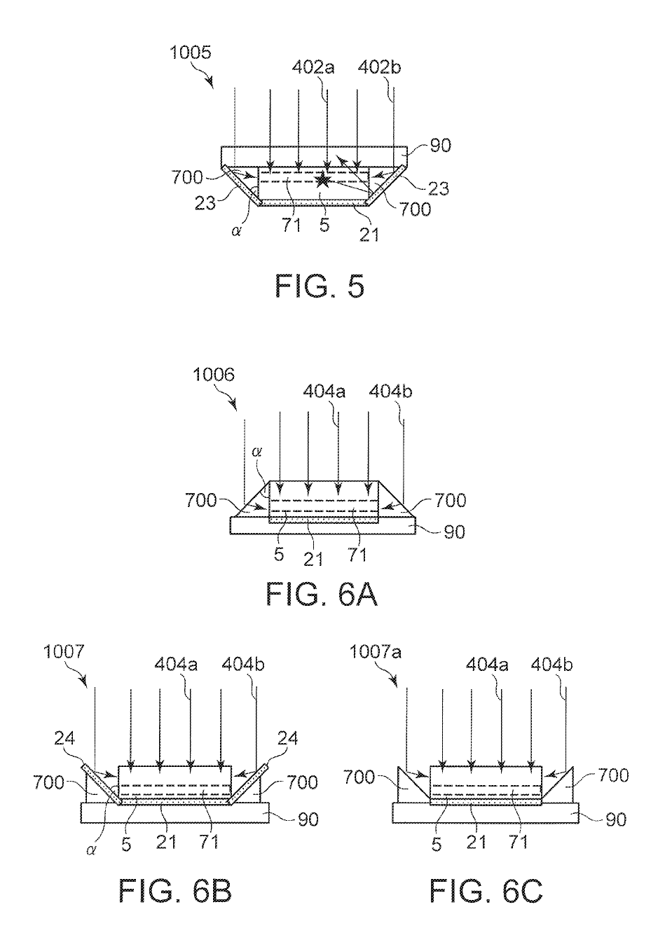

FIG. 5 is a diagram showing a photo detector 1005.

The same symbols are given to the same portions as in FIGS. 1A-1C, and the description thereof will be omitted.

The photo detector 1005 is further provided with a side surface reflective material (second reflective material) 23 in the photo detector 1002. The side surface reflective material 23 is composed of the same metal material as the reflective material 21, for example. The side surface reflective material 23 is provided on the surface of the optical path conversion portion 700 of the semiconductor layer 5, to reflect the light 402b incident into the optical path conversion portion 700 of the photo detector 1005 toward the depletion layer 71.

When a plurality of the photo detectors 1005 are aligned, in the same manner as the photo detection device 1003 in which a plurality of the photo detectors 1002 are aligned, it is possible to suppress that the light 403 generated in the avalanche amplification process is incident into the another photo detector 1005.

### Fourth Embodiment

FIG. 6A is a diagram showing a photo detector 1006, FIG. 6B is a diagram showing a photo detector 1007, and FIG. 6C is a diagram showing a photo detector 1007a.

The same symbols are given to the same portions as in FIG. 5, and the description thereof will be omitted.

In FIG. 6A, the photo detector 1006 is provided with the reflective material (first reflective material) 21 between the semiconductor layer 5 and the substrate 90.

An angle of the slope surface of the optical path conversion portion 700 to the direction from the light receiving surface toward the reflective material 21 becomes a. The angle α is not less than 10 degrees and not more than 80 degrees.

In the photo detector 1006, the semiconductor layer 5 at a side opposite to the substrate 90 side serves as the light receiving surface, in a manner different from the photo detector 1002, and lights 404a, 404b are incident on the light receiving surface. The depletion layer 71 detects not only the light 404a which has been directly incident into the semiconductor layer 5, but also the light 404b which has been incident from the optical path conversion portion 700. The light 404b which has been incident into the optical path conversion portion 700 is changed in the traveling direction by the difference between the refractive indexes of the optical path conversion portion 700 and air, and is incident into the depletion layer 71.

In the photo detector 1007 of FIG. 6B, the reflective material (first reflective material) 21 is provided between the semiconductor layer 5 and the substrate 90. The optical path conversion portion (slope portion) 700 is provided next to the semiconductor layer 5. The slope surface of the optical path conversion portion 700 reflects the light 404b toward the side surface of the semiconductor layer 5. A reflective material (second reflective material) 24 is provided on the slope surface of the optical path conversion portion 700. The reflective material 24 is supported by the optical path conversion portion 700. The angle α of the slope surface of the reflective material 24 to the surface of the semiconductor layer 5, in the direction from the reflective material 21 toward the semiconductor layer 5 is not less than 10 degrees and not more than 80 degrees.

In the photo detector 1007, the light 404a is incident into the semiconductor layer 5. The light 404a is detected by the depletion layer 71 of the semiconductor layer 5. The light 404b is incident on the reflective material 24 of the optical path conversion portion 700. The light 404b reflected by the reflective material 24 is incident into the semiconductor layer 5. The light 404b is detected by the depletion layer 71 of the semiconductor layer 5.

In the photo detector 1007, it is possible to reflect the light 404b by the slope surface of the optical path conversion portion 700 of the photo detector 1007a shown in FIG. 6C, without providing the reflective material 24.

The reflective material 24 has only to be provided on the slope surface of the optical path conversion portion 700, if necessary.

### Fifth Embodiment

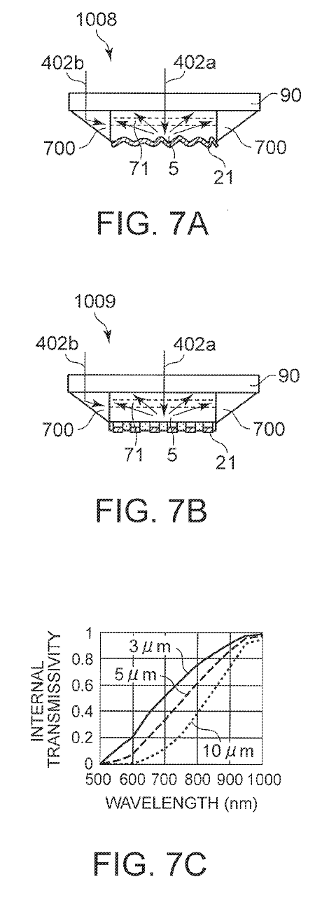

FIG. 7A is a diagram showing a photo detector 1008, FIG. 7B is a diagram showing a photo detector 1009, and FIG. 7C is a diagram showing the relation between a wavelength of light and an internal transmissivity of silicon (Si).

The same symbols are given to the same portions as in FIGS. 1A-1C, and the description thereof will be omitted.

In the photo detector 1008 of FIG. 7A, the surface of the semiconductor layer 5 at the reflective material 21 side is irregularly concave-convex. The surface of the semiconductor layer 5 with the irregularly concave-convex shape is covered with the reflective material 21. The irregularly concave-convex shape is provided in the photo detector 1008, and thereby the incident light 402a is scattered within the semiconductor layer 5.

In the photo detector 1009 of FIG. 7B, the surface of the semiconductor layer 5 at the reflective material 21 side is regularly concave-convex. The surface of the semiconductor layer 5 with the regularly concave-convex shape is covered with the reflective material 21. The regularly concave-convex shape is provided in the photo detector 1009, and thereby the incident light 402a is scattered or diffracted within the semiconductor layer 5.

The concavity/convexity of the semiconductor layer 5 may be irregular or regular.

Each of the photo detectors 1008, 1009 may be provided with the side surface reflective material 23 shown in FIG. 5 on the surface of the optical path conversion portion 700. The side surface reflective material 23 provided on the surface of the optical path conversion portion 700 reflects light toward the semiconductor layer 5.

In FIG. 7C, the vertical axis shows an internal transmissivity of light of the semiconductor layer 5, and the horizontal axis shows a wavelength of light.

In FIG. 7C, in the case of a light with a wavelength of 900 nm, for example, even if light propagates in silicon for 5 μm, about 90% of light passes through silicon, and accordingly, only about 10% of light is absorbed by silicon.

When a film thickness of the semiconductor layer 5 of each of the photo detectors 1008, 1009 is 10 μm, for example, even if the light 402a has been incident on each of the photo detectors 1008, 1009, the light 402a is not absorbed by the depletion layer 71, but is reflected by the reflective material 21, and then passes through the substrate 90 and goes outside. In order to solve this, the concave-convex structure of each of the photo detectors 1008, 1009 curves the path of the incident light 402a, totally reflects the incident light 402a by an interface of the semiconductor layer 5 and the substrate 90, and makes the light 402a stay within the semiconductor layer 5.

However, in each of the photo detectors 1008, 1009, a part of the light 402a reflected by the concave-convex structure might go outside the region of the depletion layer 71. At this time, the optical path conversion portion 700 is further provided, and thereby it is possible to reflect the light 402a which has gone outside the region of the depletion layer 71, to return the light 402a to the depletion layer 71 again.

### Sixth Embodiment

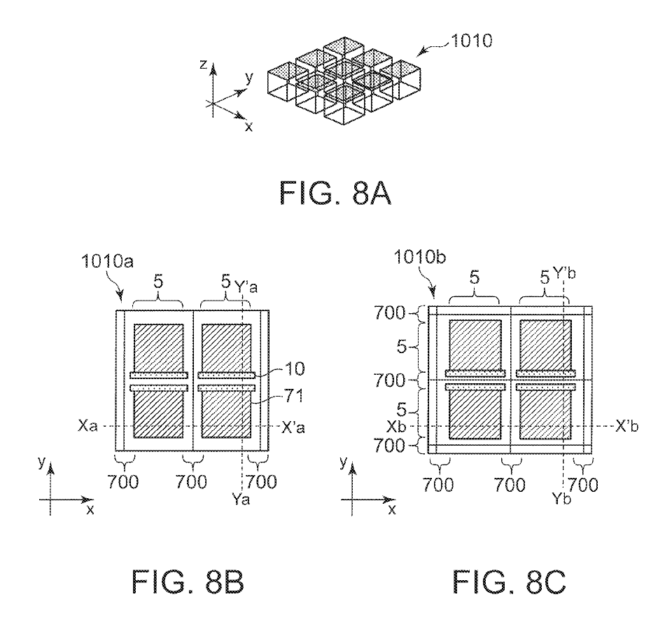

FIG. 8A is a diagram showing a photo detection device 1010, FIG. 88 is a diagram showing a photo detection device 1010a, and FIG. 8C is a diagram showing a photo detection device 1010b.

In FIG. 8A, the photo detection device 1010 is obtained by arranging a plurality of the photo detectors or the photo detection devices of any of the first to fifth embodiments.

In FIG. 8B, the photo detection device 1010a is an example of the photo detection device 1010 seen from an xy plane. In the photo detection device 1010a, a plurality of the optical path conversion portions 700 are provided separately in the x direction.

In FIG. 8C, the photo detection device 1010b is an example of the photo detection device 1010 seen from the xy plane. In the photo detection device 1010b, a plurality of the optical path conversion portions 700 are provided separately in the x direction and the y direction.

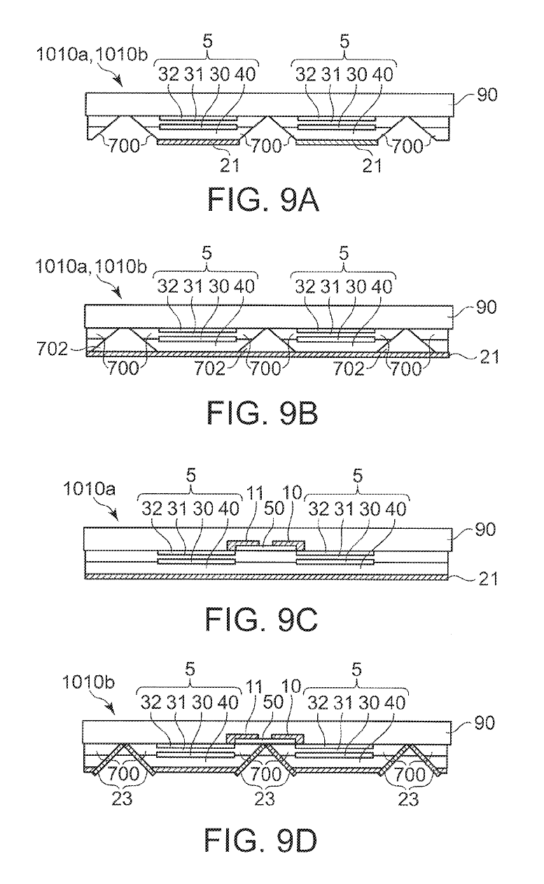

FIGS. 9A to 9D are sectional views each showing the photo detection device 1010a or 1010b. The same symbols are given to the same portions as in FIGS. 1A-1C, and the description thereof will be omitted.

FIG. 9A shows an Xa-X′ a cross section of the photo detection device 1010a or an Xb-X′b cross section of the photo detection device 1010b.

The optical path conversion portions 700 are provided in the x direction of the photo detection device 1010a or 1010b.

FIG. 9B shows an Xa-X′ a cross section of the photo detection device 1010a provided further with a filler 702 or an Xb-X′b cross section of the photo detection device 1010b provided further with the filler 702.

In FIG. 9B, the filler 702 is provided between the optical path conversion portion 700 and the optical path conversion portion 700 which are adjacent to each other. The filler 702 is composed of an organic material, an oxide or the like, for example. The filler 702 is composed of a material with a lower refractive index than the semiconductor layer 5 and the optical path conversion portion 700. The filler 702 is provided Between the optical path conversion portion 700 and the optical path conversion portion 700 which are adjacent to each other, and the reflective material 21 is further provided, and thereby it is possible to electrically connect between the photoelectric conversion regions of the respective photo detectors.

FIG. 9C shows a Ya-Y′ a cross section of the photo detection device 1010a.

The optical path conversion portion 700 is not provided in the y direction of the photo detection device 1010a.

FIG. 9D shows a Yb-Y′b cross section of the photo detection device 1010b.

The optical path conversion portions 700 are provided in the y direction of the photo detection device 1010b.

The side surface reflective material 23 is provided on the surface of the optical path conversion portion 700. The side surface reflective material 23 is provided, to suppress the effect of the light 403 generated inside the photo detector, in the same manner as the photo detector 1005 shown in FIG. 5. In addition, the side surface reflective material 23 is composed of a metal material, and thereby it is possible to electrically connect between the photoelectric conversion regions of the respective photo detectors.

### Seventh Embodiment

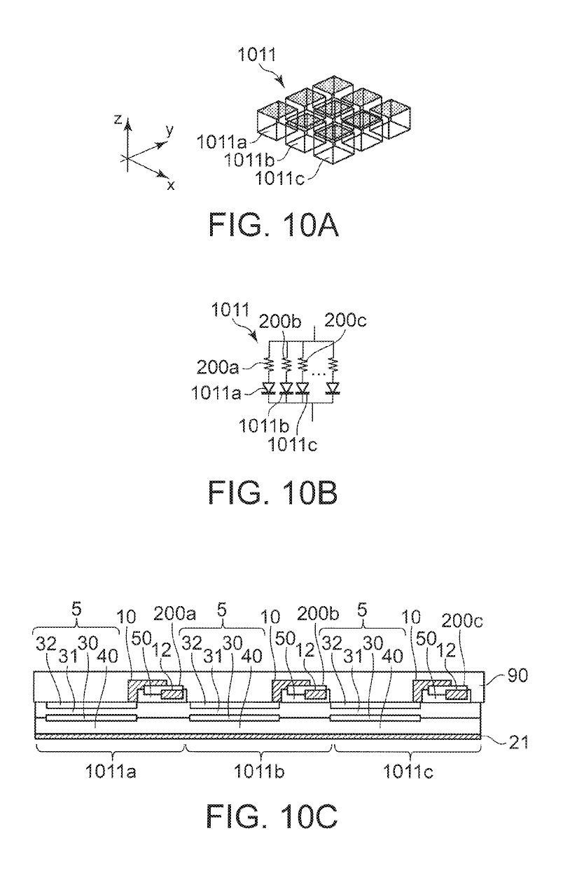

FIG. 10A is a diagram showing a photo detection device 1011, FIG. 10B is a circuit diagram of the photo detection device 1011, and FIG. 10C is a sectional view of the photo detection device 1011.

In FIG. 10A, the photo detection device 1011 is composed by arranging a plurality of photo detectors 1011a, 1011b, 1011c. The plurality of photo detectors 1011a, 1011b, 1011c share the same substrate, for example.

In FIG. 10B, a quench resistor 200a is connected to the photo detector 1011a. A quench resistor 200b is connected to the photo detector 1011b. A quench resistor 200c is connected to the photo detector 1011c.

Each of the photo detectors 1011a, 1011b, 1011c is the photo detector shown in any of the first to fifth embodiments. The photo detectors 1011a, 1011b, 1011c are respectively connected in parallel with each other via the quench resistors. When the photo detector is an avalanche photo detector, the quench resistor is used for adjusting a speed for taking out the electric charge within the photo detector.

In FIG. 10C, each of insulating layers 50 is provided at the same side as the p⁺ type semiconductor layer 32 serving as the light receiving surface of each of the photo detectors 1011a, 1011b, 1011c.

Each of first electrodes 10 is provided at the same side as the p⁺ type semiconductor layer 32 serving as the light receiving surface of each of the photo detectors 1011a, 1011b, 1011c. The first electrode 10 is provided so as to cover a part of the p⁺ type semiconductor layer 32 and the insulating layer 50.

In FIG. 10C, the quench resistor 200a and a wire 12 are provided in the photo detector 1011a. The quench resistor 200b and the wire 12 are provided in the photo detector 1011b. The quench resistor 200c and the wire 12 are provided in the photo detector 1011c. The wires 12 connect between the respective quench resistors 200a, 200b, 200c.

The p⁺ type semiconductor layer 32 of the photo detector 1011a is connected to the quench resistor 200a via the first electrode 10. The p⁺ type semiconductor layer 32 of the photo detector 1011b is connected to the quench resistor 200b via the first electrode 10. The p⁺ type semiconductor layer 32 of the photo detector 1011c is connected to the quench resistor 200c via the first electrode 10.

### Eighth Embodiment

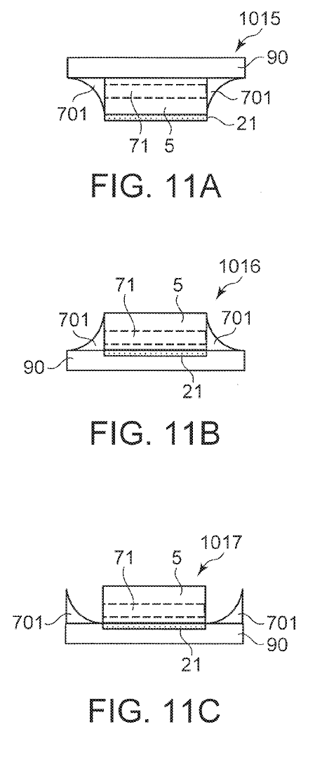

FIG. 11A is a diagram showing a photo detector 1015, FIG. 11B is a diagram showing a photo detector 1016, and FIG. 11C is a diagram showing a photo detector 1017.

The same numbers are given to the same portions as in FIGS. 1A-1C and FIGS. 6A-6C which have been described above, and the description thereof will be omitted. In FIG. 11A, an optical path conversion portion (slope portion) 701 that is a side surface of the semiconductor layer 5 of the photo detector 1015 has an arc surface which is formed of an arc shape in the direction from the reflective material 21 toward the light receiving surface side of semiconductor layer 5. Light reflected by the side surface of the optical path conversion portion 701 that is the side surface of the semiconductor layer 5 of the photo detector 1015 is incident into the semiconductor layer 5. The light which has been reflected by the side surface of the optical path conversion portion 701 that is the side surface of the semiconductor layer 5 of the photo detector 1015 and has been incident into the semiconductor layer 5 is absorbed by the depletion layer 71.

In FIG. 11B, the optical path conversion portion 701 that is a side surface of the semiconductor layer 5 of the photo detector 1016 has an arc surface which is formed of an arc shape in the direction from the light receiving surface side of the semiconductor layer 5 toward the reflective material 21. Light which has been incident into the side surface of the optical path conversion portion 701 that is the side surface of the semiconductor layer 5 of the photo detector 1016 is refracted by the side surface of the optical path conversion portion 701, and is incident into the semiconductor layer 5. The light which has been incident into the semiconductor layer 5 is absorbed by the depletion layer 71.

In FIG. 11C, the optical path conversion portion 701 is provided next to the semiconductor layer 5 of the photo detector 1017. The optical path conversion portion 701 has an arc surface which is formed of an arc shape in the direction from the reflective material 21 toward the light receiving surface of the semiconductor layer 5. The optical path conversion portion 701 is provided next to the semiconductor layer 5. Light which has been incident on the arc surface of the optical path conversion portion 701 is reflected by the arc surface. The light which has been reflected by the arc surface of the optical path conversion portion 701 is incident into the semiconductor layer 5. The light which has been incident into the semiconductor layer 5 is absorbed by the depletion layer 71.

In addition, the optical path conversion portion 701 may be a part of the semiconductor layer 5, or may be a portion separate from the semiconductor layer 5.

### (Manufacturing Method)

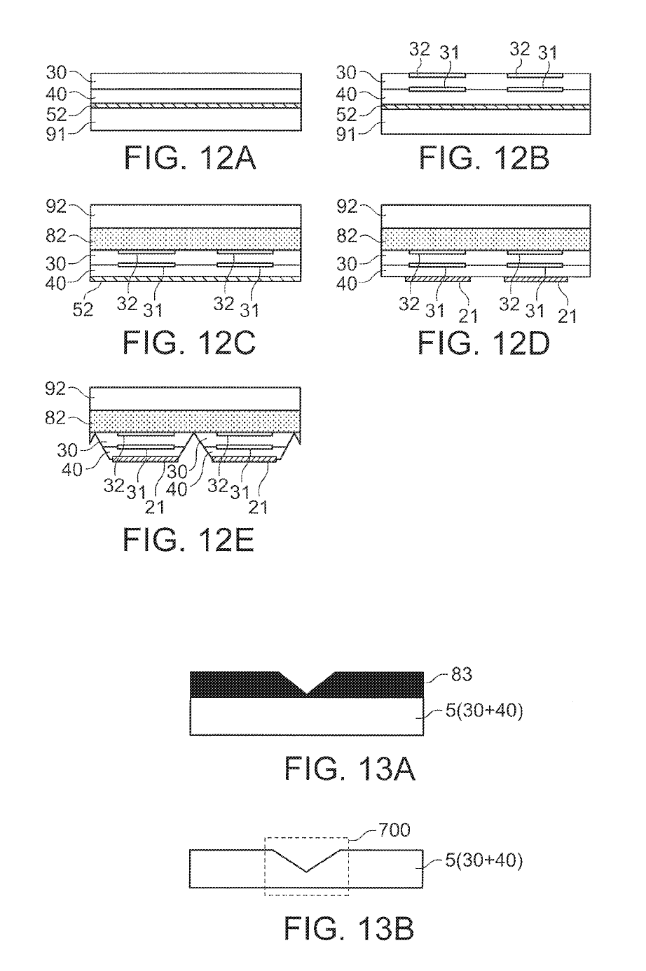

FIGS. 12A to 12E are diagrams showing a manufacturing method of the photo detector 1003. Here, an example of a case to use Si as the semiconductor material will be shown.

To begin with, as shown in FIG. 12A, an SOI (Silicon On Insulator) substrate is prepared. The SOI substrate has a structure in which a silicon substrate 91, a BOX (buried oxide layer) 52, an active layer (n type semiconductor layer) 40 are laminated in this order. The p⁻ type semiconductor layer 30 is formed on the n type semiconductor layer 40 by epitaxial growth.

As shown in FIG. 12B, impurities (boron, for example) are implanted into the p⁻ type semiconductor layer 30 so that a part of the region of the p⁻ type semiconductor layer 30, that is a region in which the photo detector is to be formed, becomes the p⁺ type semiconductor layer 31. By this means, the p⁺ type semiconductor layer 31 composing a photo detection element is formed on portion of the active layer 40 of the SOI substrate. In addition, a first mask not shown is formed on the p⁻ type semiconductor layer 30, and p type impurities are implanted into the p⁻ type semiconductor layer 30 using this first mask, to form the p⁺ type semiconductor layer 32 on the p⁻ type semiconductor layer 30 serving as a photo detection region.

After the first mask has been removed, a second mask not shown is formed on the p⁺ type semiconductor layer 32. The insulating layer 50 not shown is formed on the p⁻ type semiconductor layer 30 using this second mask, and the first electrode 10 not shown is formed so as to cover the insulating layer 50 and a peripheral portion of the type semiconductor layer 32. For example, metal such as Ag, Al, Au, Cu or an alloy thereof is used for the first electrode 10. After the first electrode 10 has been formed, the second mask is removed, and a passivation layer 82 is formed so as to cover the first electrode and a part of the p⁺ type semiconductor layer 32. The passivation layer 82 is composed of an oxide film or photo resist, for example.

As shown in FIG. 12C, a support substrate 92 is provided on the passivation layer 82. The support substrate 92 may be directly adhered to the passivation layer 82, or the support substrate 92 and the passivation layer 82 may be adhered to each other using an adhesive layer not shown. After the support substrate 92 has been provided, the silicon substrate 91 is subjected to dry etching. In this dry etching, a reaction gas such as SF₆ can be used, for example. When a reaction gas having etch selectivity of the silicon substrate 91 and the BOX 52 is used in this dry etching, the BOX 52 can be used as an etching stop film. In addition, when the silicon substrate 91 is sufficiently thick, a polishing process such as back grinding and CMP (Chemical Mechanical Polishing), or wet etching may be used together. When wet etching is used, KOH or TMAH (Tetra-Methyl-Ammonium Hydroxide) can be used as etchant. When the silicon substrate 91 is etched by means of this, the BOX 52 is exposed.

As shown in FIG. 12D, the exposed BOX 52 is removed by etching, and thereby the n type semiconductor layer 40 is exposed. Wet etching with hydrofluoric acid or the like can be used, as this etching. Wet etching like this is used, while sufficiently ensuring etch selectivity of the BOX 52 and silicon, the exposed BOX 52 can be selectively removed. After the n type semiconductor layer 40 has been exposed, the reflective material 21 is provided in the region serving as the photo detection region.

As shown in FIG. 12E, the optical path conversion portion 700 is formed at the peripheral portion of the reflective material 21, using wet etching or dry etching. In the case of the wet etching, anisotropic etching and isotropic etching can be used. In the case of the anisotropic etching, the optical path conversion portion 700 having a slope angle which determined by a crystal face of the semiconductor layer 5 that is composed of the p⁻ type semiconductor layer 30 and the n type semiconductor layer 40 is formed. In addition, in the case of the isotropic etching, the slope surface can be formed of an arc shape. In the case of the dry etching, the slope surface can be formed of an arc shape. In the case of the dry etching, as shown in FIG. 13A, a resist 83 having a slope surface is provided on the semiconductor layer 5, for example, and thereby the optical path conversion portion 700 having an arbitrary slope angle in accordance with the slope surface of the resist 83 can be formed, as shown in FIG. 13B.

### Ninth Embodiment

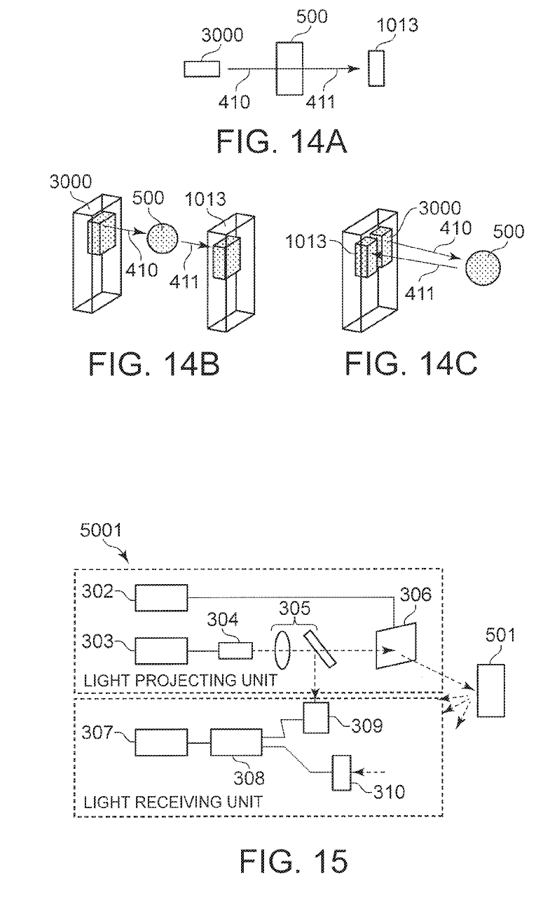

FIG. 14A is a diagram showing a measuring system, and FIGS. 14B, 14C are diagrams each showing a specific example of the measuring system.

In FIG. 14A, the measuring system is composed of at least a photo detection device 1013 and a light source 3000. In the measuring system, the light source 3000 emits a light 410 to a measuring object 500. The photo detection device 1013 detects a light 411 which has passed through the measuring object 500 or has reflected or diffused from the measuring object 500. The measuring system may be configured such that the light source 3000 and the photo detection device 1013 are respectively housed in separate chassis, as shown in FIG. 14B, for example. Or the light source 3000 and the photo detection device 1013 may be housed in the same chassis, as shown in FIG. 14C. Any of the photo detectors and the photo detection devices which have been described above is used as the photo detection device 1013, and thereby it is possible to realize a measuring system with high sensitivity, particularly in the near infra-red region.

### Tenth Embodiment

FIG. 15 is a diagram showing a LIDAR (Laser Imaging Detection and Ranging) device 5001.

The LIDAR device 5001 is provided with a light projecting unit and a light receiving unit.

The light projecting unit is composed of a light oscillator 304, a drive circuit 303, an optical system 305, a scan mirror 306, and a scan mirror controller 302. The light receiving unit is composed of a reference light detector 309, a photo detection device 310, a distance measuring circuit 308, and an image recognition system 307.

In the light projecting unit, the laser light oscillator 304 emits laser light. The drive circuit 303 drives the laser light oscillator 304. The optical system 305 extracts a part of the laser light as reference light, and irradiates an object 501 with the other laser light via the mirror 306. The scan mirror controller 302 controls the scan mirror 306, to irradiate the object 501 with the laser light.

In the light receiving unit, the reference light detection device 309 detects the reference light extracted by the optical system 305. The photo detection device 310 receives the reflected light from the object 501. The distance measuring circuit 308 measures a distance to the object 501, based on the reference light detected by the reference light photo detection device 309 and the reflected light detected by the photo detection device 310. The image recognition system 307 recognizes the object 501, based on the result measured by the distance measuring circuit 308.

The LIDAR device 5001 is a distance image sensing system employing a light flight time ranging method (Time of Flight) which measures a time required for a laser light to reciprocate to a target, and converts the time into a distance. The LIDAR device 5001 is applied to an on-vehicle drive-assist system, remote sensing, and so on. If any of the photo detectors and the photo detection devices which have been described above is used as the photo detection device 310, the LIDAR device 5001 expresses good sensitivity, particularly in a near infra-red region. For this reason, it becomes possible to apply the LIDAR device 5001 to a light source in a human-invisible wavelength band. The LIDAR device 5001 can be used for obstacle detection for vehicle, for example.

While certain embodiments have been described, these embodiments have been presented by way of example only, and are not intended to limit the scope of the inventions. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photo detector, comprising:
a semiconductor layer having a light receiving surface;
a first reflective material which is provided on a side opposite to the light receiving surface side of the semiconductor layer and reflects a light incident from the light receiving surface; and
a slope portion provided on a side surface of the semiconductor layer.

2. The photo detector according to claim 1, further comprising:
a substrate to transmit the light on the light receiving surface of the semiconductor layer.

3. The photo detector according to claim 1, wherein:
an angle of a slope surface of the slope portion to a direction from the first reflective material toward the light receiving surface is not less than 10 degrees and not more than 80 degrees.

4. The photo detector according to claim 1, wherein:
an angle of a slope surface of the slope portion to direction from the first reflective material toward the light receiving surface is not less than 45 degrees and not more than 75 degrees.

5. The photo detector according to claim 1, further comprising:
a second reflective material which covers a surface of the slope portion and reflects the light incident from the light receiving surface.

6. The photo detector according to claim 1, wherein:
the semiconductor layer has a concave-convex portion on a surface thereof at the first reflective material side.

7. The photo detector according to claim 1, wherein:
the slope portion is a part of the semiconductor layer.

8. The photo detector according to claim 1, further comprising:
a substrate at a side of the first reflective material of the semiconductor layer.

9. The photo detector according to claim 1, wherein:
an angle of a slope surface of the slope portion of the semiconductor layer to a direction from the light receiving surface toward the first reflective material is not less than 10 degrees and not more than 80 degrees.

10. The photo detector according to claim 2, wherein:
a slope surface of the slope portion is an arc surface formed of an arc shape.

11. A photo detector, comprising:
a semiconductor layer having a light receiving surface;
a substrate provided at a side opposite to the light receiving surface side of the semiconductor layer;
a first reflective material which is provided between the semiconductor layer and the substrate, and reflects a light incident from the light receiving surface; and
a slope portion which is provided next to the semiconductor layer, and has a slope surface to reflect a light toward a side surface of the semiconductor layer.

12. The photo detector according to claim 11, wherein:
an angle of the slope surface of the slope portion to the side surface of the semiconductor layer, in a direction from the first reflective material toward the light receiving surface is not less than 10 degrees and not more than 80 degrees.

13. The photo detector according to claim 11, wherein:
the slope surface of the slope portion is an arc surface formed of an arc shape.

14. The photo detector according to claim 11, wherein:
the semiconductor layer includes a p type semiconductor layer and an n type semiconductor layer in this order in a direction from the light receiving surface toward the first reflective material.

15. The photo detector according to claim 14, wherein:
the semiconductor layer includes a p⁺ type semiconductor layer, a p⁻ type semiconductor layer, a p⁺ type semiconductor layer, and the n type semiconductor layer in this order, in the direction from the light receiving surface toward the first reflective material.

16. The photo detector according to claim 11, wherein:
the semiconductor layer includes an n type semiconductor layer, and a p type semiconductor layer in this order, in a direction from the light receiving surface toward the first reflective material.

17. The photo detector according to claim 16, wherein:
the semiconductor layer includes an n⁺ type semiconductor layer, an n⁻ type semiconductor layer, an n⁺ type semiconductor layer, and the p type semiconductor layer in this order, in the direction from the light receiving surface toward the first reflective material.

18. The photo detector according to claim 11, wherein:
a length of the semiconductor layer in a direction from the light receiving surface toward the first reflective material is not less than 1 μm and not more than 15 μm.

19. A photo detection device, comprising:
a plurality of the arranged photo detectors according to claim 11.

20. A LIDAR device, comprising:
a light source to irradiate an object with light;
the photo detection device according to claim 19 which detects the light reflected by the object; and
a measuring unit to measure a distance between the object and the photo detection device.
